(19) United States
(12) Patent Application Publication
(10) Pub. No.: US 2009/0309660 A1
(43) Pub. Date: Dec. 17, 2009

(54) DEVICE FOR AMPLIFYING A BROADBAND RF SIGNAL

(75) Inventors: Benoit Mallet-Guy, Paris (FR); Thierry Dequen, Maurepas (FR)

Correspondence Address: DARBY & DARBY P.C., P.O. BOX 770, Church Street Station, New York, NY, 10008-0770, US

(73) Assignee: Thales, Neuilly Sur Seine (FR)

(21) Appl. No.: 12/307,775

(22) PCT Filed: Jul. 5, 2007
(86) PCT No.: PCT/EP07/56821

§ 371 Date: Aug. 21, 2009

(30) Foreign Application Priority Data
Jul. 7, 2006 (FR) 06 06216

(51) Int. Cl. H03F 3/16

(52) U.S. Cl. 330/277

(57) ABSTRACT

The present invention relates to a microwave signal amplification device comprising a cascode cell (60). The cascode cell comprises at least two transistors (31, 32). The gate of a first transistor (31) is connected to the input (E) of said device, the drain of the second transistor (32) is connected to the output (S), and the source of the second transistor (32) is connected to the drain of the first transistor (31). A variable-impedance circuit (50) is connected to the gate of the second transistor (32). Embodiments of the invention are used notably for microwave receivers, for example in the case of high bit rate links or other applications requiring reception over a broad band of frequencies.

### CROSS-REFERENCE TO PRIOR APPLICATION

This is a U.S. National Phase application under 35. U.S.C. §371 of International Application No. PCT/EP2007/056821, filed Jul. 5, 2007, and claims benefit of French Patent Application No. 06 06216, filed Jul. 7, 2006, both of which are incorporated herein in their entireties. The International Application was published in French on Jan. 10, 2008 as WO 2008/003751 under PCT 21(2).

### BACKGROUND OF THE INVENTION

The present invention relates to a broadband microwave signal amplification device. This invention is used notably for microwave receivers, for example in the case of high bit rate links or other applications requiring reception over a broad band of frequencies.

### BRIEF DESCRIPTION OF THE PRIOR ART

For certain applications, microwave signal receivers have integrated receive circuits rising very high in frequency. These receive circuits require amplifications of the received signals. Broadband amplifiers are therefore used. These amplifiers, in addition to being broadband, must have a high gain for a low noise factor and be made with small dimensions.

Amongst the broadband amplifiers used, two architectures are notably known: a distributed architecture and a counter-reaction architecture.

The distributed amplifier has an architecture allowing operation over a broad band. The circuits using this architecture have a gain of the order of 10 dB for a noise factor of 4 to 5 dB usually. A known enhancement of this structure consists in replacing each transistor of the amplifier with a cell of the cascode type. Such an architecture makes it possible to obtain a gain of the order of 13 dB while increasing the power level of the output signal of the amplifier. The main disadvantages of this type of architecture are the relatively high noise level and the size which remains considerable even when using a monolithic microwave integrated circuit or MMIC technology.

The counter-reaction architecture consists in inserting a circuit of the low-pass type between the input and the output of a transistor. This architecture makes it possible to obtain a constant gain over a frequency range. One enhancement consists in using a cascode cell instead of the transistor, which makes it possible to have a gain of the order of 13 dB for an assembly of reduced size. Nevertheless, such an assembly has an insufficient frequency bandwidth and is therefore not suitable for a broadband application.

### SUMMARY OF THE INVENTION

One object of the invention is notably to alleviate the aforementioned disadvantages. Accordingly, the subject of the invention is a microwave signal amplification device comprising a cascode cell. The cascode cell comprises at least two transistors. The gate of a first transistor is connected to the input of said device. The drain of the second transistor is connected to the output of said device. The source of the second transistor is connected to the drain of the first transistor.

A variable-impedance circuit is for example connected to the gate of the second transistor and varies according to the frequency of the input signal.

The variable-impedance circuit comprises an inductance and a resistance mounted in series; it is connected between the gate of the second transistor and a reference potential.

The transistors used in the device may be field-effect transistors.

Since the cascode cell is counter-reaction, a low-pass filter is for example connected between the input and the output of the device. The low-pass filter comprises an inductance and a resistance mounted in series. The inductance comprises a fixed portion and an adjustable portion made in MMIC technology.

Notably, the main advantages of the invention are to reduce the cost of a chip incorporating a broadband amplifier, while having a very broad band operation associated with a positive gain and with a low level of noise.

### BRIEF DESCRIPTION OF THE DRAWINGS

Other features and advantages of the invention will appear with the aid of the following description given with respect to the appended drawings which represent:

FIG. 1: an example of a known distributed amplifier;

FIG. 2: an example of counter-reaction architecture;

FIG. 3: a diagram of a cascode cell;

FIG. 4: a diagram of a counter-reaction cascode cell according to the prior art;

FIG. 5: a first exemplary embodiment of an amplification device according to the invention;

FIG. 6: a second exemplary embodiment of a counter-reaction cascode cell with variable-gate impedance according to the invention;

FIGS. 7a and 7b: an exemplary embodiment of an amplification device according to the invention.

### DETAILED DESCRIPTION

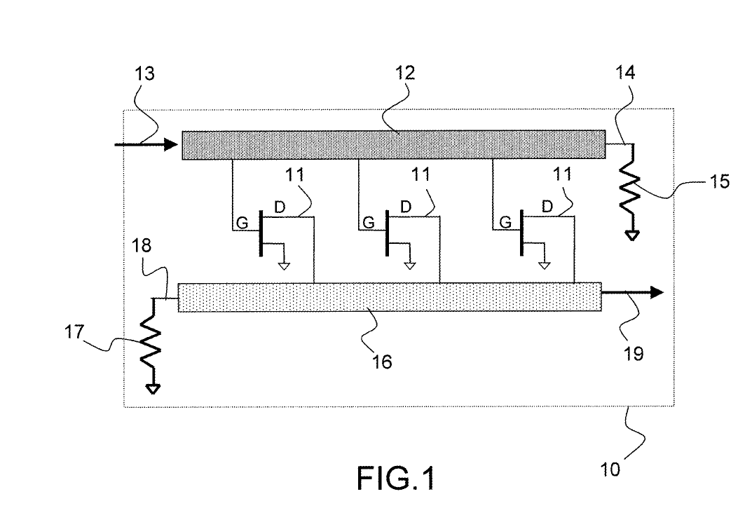

FIG. 1 represents a diagram of an amplifier 10 having a distributed architecture according to the prior art. This distributed amplifier 10 comprises N amplifying cells mounted in parallel, based on one or more field-effect transistors. In the example of FIG. 1, each amplifying cell comprises a transistor 11 which may for example be a field-effect transistor. The gate of a transistor 11 is connected to a common line of gates 12 which extends from an input point of the assembly 13 to an access point 14 to which is connected a resistance 15 connected to a reference potential. The drain of the transistor 11 is connected to a line of common drains 16 which extends between a resistance 17 and an output point 19 of the assembly. The resistance 17 is mounted on an access 18 of the line of drains 16 and connected to a reference potential. The source of the transistor 11 is connected to the reference potential. In what follows, the reference potential will be assimilated to the electric zero or to the frame ground.

The lines of gates 12 and of drains 16 are lines consisting essentially of capacitors inside the transistors and inductances optionally connected by mutual inductances. These inductances are notably designed to adapt the line to a characteristic impedance for example of 50 Ohms.

The input of the common line of gates 12 forms the input 13 of the distributed amplifier 10. The other end 14 of the line of gates is loaded on a terminal resistance or subsidiary load 15 whose resistance value is substantially equal to the characteristic impedance of the common line of gates 12.

As on the line of gates 12, one of the ends of the common line of drains 16 is loaded on a terminal resistance 17 whose resistance value is substantially equal to the characteristic impedance of the common line of drains 16, while the other end of the common line of drains 16 defines the output 19 of the distributed amplifier.

A bias circuit not represented in FIG. 1 applies a direct bias voltage to the common line of gates 12.

The operation of a distributed amplifier of the type illustrated in FIG. 1 is as follows. A microwave signal received at the input 13 is propagated on the common line of gates 12 to be absorbed by the subsidiary load 15. Onto each gate of transistors 11 therefore a signal travels, being propagated from the input 13 to the subsidiary load 15. This signal is propagated through the transistors 11 to the output 19, the other end of the line of drains 16 being loaded by its characteristic impedance. This microwave signal being amplified by the transistors 11, the amplification has a very wide bandwidth because it begins from the direct current to the chopping frequencies associated with the characteristics of the transistors 11. These chopping frequencies may be extremely high, from several tens of GHz to a hundred GHz.

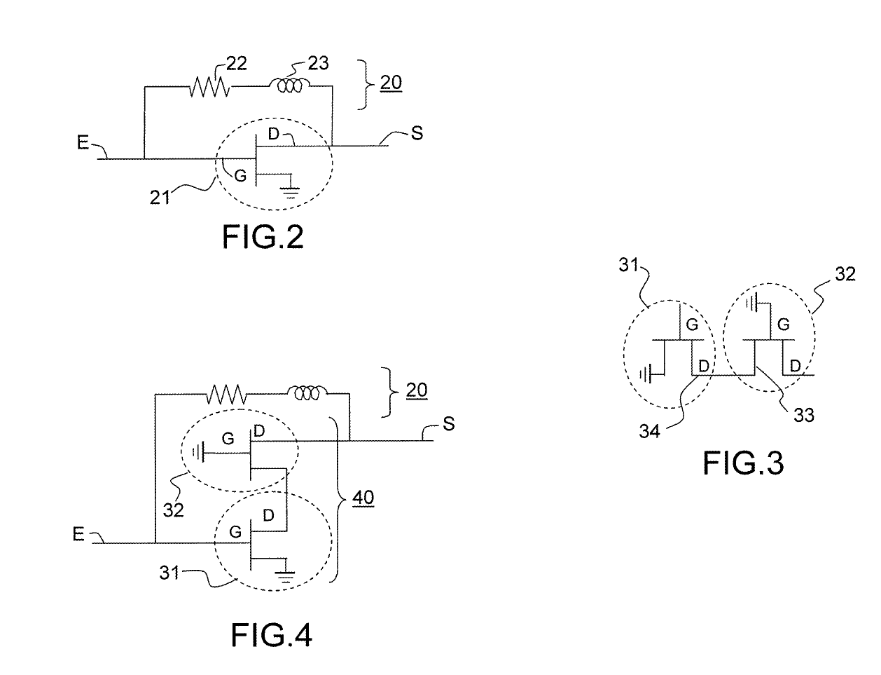

FIG. 2 shows an example of an amplifying circuit according to a counter-reaction architecture. The counter-reaction architecture consists in inserting between the input E and the output S of a set of transistors 21 a circuit 20 forming a low-pass filter. In FIG. 2, the set of transistors is represented by one transistor 21, the input of the circuit E being connected to the gate G of the transistor 21 and the output S of the circuit being connected to the drain D of the transistor 21.

In the example of FIG. 2, the low-pass circuit 20 consists of an inductance 23 and a resistance 22. The resistance 22 is connected to the input E of the circuit and the inductance 23 is connected to the output S of the amplifying circuit.

The low-frequency signals pass through the counter-reaction circuit 20, forming the low-pass filter, and are therefore not amplified. On the other hand, the high-frequency signals pass through the transistor 21 which amplifies them. A direct bias voltage is also applied to the gate G of the transistor 21 in order to put it in the on state.

The counter-reaction is associated with the natural inverse gain gradient of the transistor, and the result of this is a fairly constant gain over the operating range of the amplifying circuit.

The width of the operating frequency band of such an architecture is insufficient for a broadband application for which a ratio of the order of 20 between the minimum frequency and the maximum frequency is for example sought.

FIG. 3 shows the diagram of a known cascode cell. This cascode cell may be used to improve the performance of the two architectures presented above. This is because, in both cases, it makes it possible to obtain a higher gain, greater than 10 dB.

This cascode cell comprises for example two field-effect transistors 31 and 32, the second transistor 32 having its source 33 connected to the drain 34 of the first transistor 31. The source of the transistor 31 and the gate of the transistor 32 are connected to a reference potential. A bias circuit not shown applies a direct voltage to the gates of the transistors 31 and 32 in order to place the latter in the on state. Implicitly, at the gate of transistor 32, an impedance separates the bias circuit from the reference potential, as would be known by a person of ordinary skill in the art of circuit design.

FIG. 4 represents a cascode cell used in a counter-reaction architecture, the whole forming an amplifying circuit according to the prior art. This circuit therefore comprises a cascode cell 40 as described in FIG. 3, and a low-pass circuit 20 as described with reference to FIG. 2. The input E of the amplifying circuit is connected to the gate of the transistor 31 and the output S of the circuit is connected to the drain of the transistor 32.

This architecture has a very small footprint and a high gain, greater than 10 dB. Nevertheless such a circuit still does not have a sufficiently wide bandwidth.

FIG. 5 represents an exemplary embodiment of an amplification device according to the invention. This device comprises a cascode cell 60 as described with reference to FIG. 3. The signal is input into the cascode cell according to an embodiment of the invention to the gate of the transistor 31, the signal is output by the drain of the transistor 32. According to an embodiment of the invention, a variable-impedance circuit 50 is connected between the gate G of the second transistor 32 and the reference potential, for example the frame ground or the electric zero. The variable impedance of the circuit 50 depends on the frequency of the received signal. This impedance may vary linearly or pseudolinearly depending on the frequency. The variable-impedance circuit 50 behaves like a counter-reaction circuit thereby making it possible to widen the frequency band of the cascode cell. In particular, it is possible to adjust the gain gradient, positive or negative, of the device depending on the chosen impedance value. The variable-impedance circuit 50 may participate in the alternating operation of the transistor 32 by providing a degree of additional adjustment to the cascode cell 60 thereby making it possible to widen the operating frequency band.

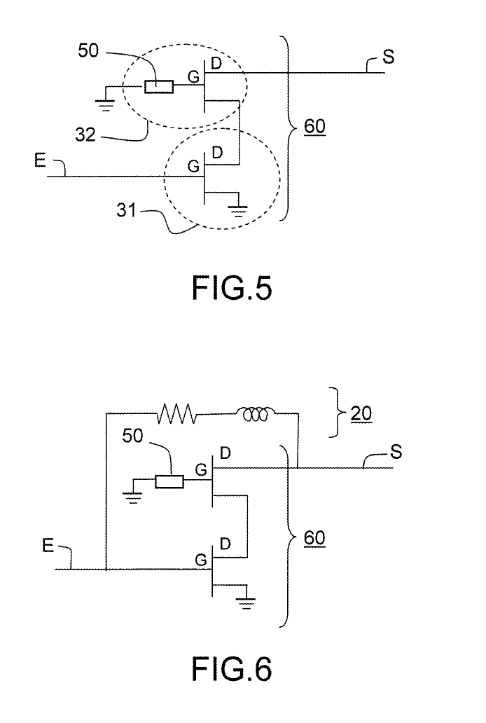

FIG. 6 shows another exemplary embodiment of a device according to the invention. In this example, the device comprises a counter-reaction as shown in FIG. 4, using the cascode cell 60 according to an embodiment of the invention described with reference to FIG. 5. This cascode cell 60 is associated with a low-pass filter 20. The counter-reaction applied to the variable-impedance cascode cell adds to the amplifying circuit of FIG. 5 the advantages of a counter-reaction amplifier. The counter-reaction circuit 20 is made use of in order to widen the operating frequency band of the amplifying circuit using the cascode cell 60 according to an embodiment of the invention. The amplifying circuit, or counter-reaction cascode cell with variable-gate impedance, is therefore a broadband circuit. The counter-reaction effect, provided by an embodiment of the invention, associated with the variable-gate impedance, allows an additional circuit design parameter on which it is possible to act to increase the operating frequency band of the circuit. This amplifying circuit makes it possible to obtain the same bandwidths as those usually obtained with a distributed architecture as in FIG. 1 for example. Used with an MMIC technology, the cascode cell according to an embodiment of the invention makes it possible to reduce the size of a broadband amplifier by a factor of two.

The noise performance is also improved since the maximum noise factor of a distributed amplifier, like the one represented in FIG. 4 for example, is typically 4 dB compared with 2.5 dB for the counter-reaction cascode cell with variable-gate impedance according to an embodiment of the invention.

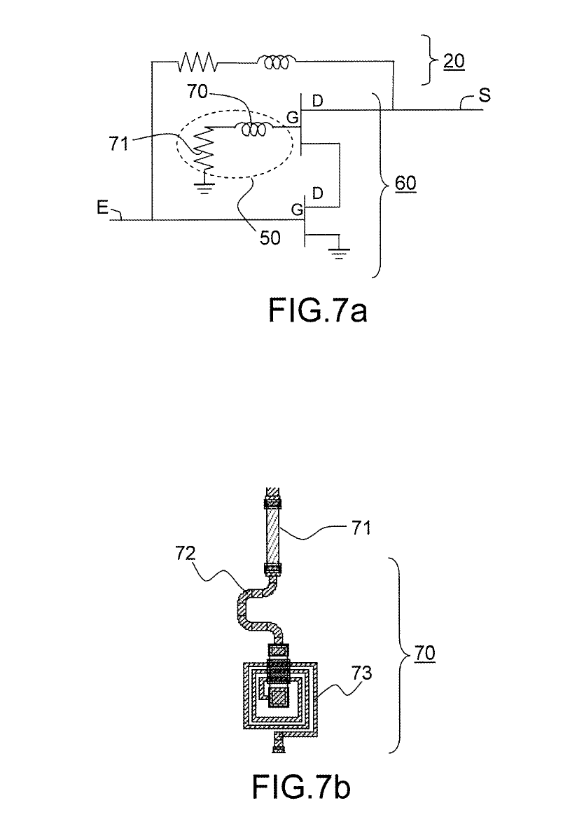

FIGS. 7a and 7b show a possible embodiment of a device according to the invention.

FIG. 7a shows an embodiment of the variable-impedance circuit 50 in MMIC technology. In the example of FIG. 7a, the variable-impedance circuit consists of an inductance 70 and a resistance 71. In a microwave integrated circuit, the variable impedance 50 of the circuit may be easily synthesized by a resistance 71 of high value, for example 2kΩ, mounted in series with a small inductance 70. The resistance 71 is itself connected to a reference potential, as illustrated by FIG. 7a.

FIG. 7b shows an example of implementation of a variable-impedance circuit on a mask of an amplifier not shown using MMIC technology. The variable-impedance circuit 50 shown schematically in FIG. 7a is found on the mask with the resistance 71 and the inductance 70. On this mask, the inductance 70 consists of a fixed portion 73 and an adjustable portion 72. The fixed portion 73 is for example formed by a winding of conductive tracks forming concentric squares. Between the resistance 71 and the fixed inductance 73 there is an [[line]] adjustable portion 72 which makes it possible to adjust the value of the inductance 70. This value is adjusted by varying the length of this [[line]] adjustable portion 72.

Embodiments of the present invention may notably be used in order to produce broadband amplifiers with a positive gain gradient, which may find their application in a broadband microwave chain or system, notably in receive mode.

The production of an amplifier with a circuit comprising a single cascode cell makes it possible to considerably reduce the size of the integrated circuit in which the cascode cell, according to an embodiment of the invention, is implemented. Since the manufacturing cost of an integrated circuit is directly linked to its surface area, embodiments of the invention make it possible to reduce the manufacturing cost of the amplifier.

The variable-gate-impedance cascode cell according to embodiments of the invention used in a counter-reaction architecture advantageously make it possible to obtain a very broad band amplifier having a relatively low noise factor and a high gain.

1. A cascode cell microwave signal amplification device comprising:
a first transistor, a gate of the first transistor corresponding to an input of said device, and a source of the first transistor connected to a reference potential;
a second transistor, a drain of the second transistor corresponding to an output of said device, a source of the second transistor connected to a drain of the first transistor;
a bias circuit connected to the gate of the first transistor and a gate of the second transistor, and
a variable-impedance circuit having a first node connected to the gate of the second transistor, and having a second node connected to the reference potential.

2. The device as claimed in claim 1, wherein an impedance of the variable-impedance circuit varies according to a frequency of the input signal.

3. The device as claimed in claim 1, wherein the variable-impedance circuit comprises an inductance and a resistance mounted in series.

4. The device as claimed in claim 1, wherein the variable-impedance circuit is connected between the gate of the second transistor and a reference potential.

5. The device as claimed in claim 1, wherein the first and second transistors are field-effect transistors.

6. The device as claimed in claim 1, wherein the cascode cell is a counter-reaction architecture, further comprising a low-pass filter connected between the input of the device and the output of the device.

7. The device as claimed in claim 6, wherein the low-pass filter comprises an inductance and a resistance mounted in series.

8. The device as claimed in claim 7, wherein the inductance comprises a fixed portion and an adjustable portion made in MMIC technology.
